(19) United States
(12) Patent Application Publication
(10) Pub. No.: US 2025/0306247 A1
(43) Pub. Date: Oct. 2, 2025

(54) METAL FLUORIDE AND PLASMA ASSISTED ATOMIC LAYER DEPOSITION COATING

(71) Applicant: CORNING INCORPORATED, CORNING, NY (US)

(72) Inventors: Donald Erwin Allen, Painted Post, NY (US); Karla Benware, Painted Post, NY (US); Jing Du, Pittsford, NY (US); Hoon Kim, Seongnam-Si (KR); Prakash Ramanath Kota, East Greenbush, NY (US)

(21) Appl. No.: 19/082,878

(22) Filed: Mar. 18, 2025

Related U.S. Application Data
(60) Provisional application No. 63/569,823, filed on Mar. 26, 2024.

(51) Int. Cl. G02B 1/115; C03C 17/09; C03C 17/34

(52) U.S. Cl. CPC G02B 1/115; C03C 17/09; C03C 17/3452; C03C 2217/285; C03C 2218/152

(57) ABSTRACT

A coated optical component including a substrate comprising at least one surface and an atomic layer deposition coating deposited on the surface of the substrate, the atomic layer deposition coating comprising a first layer of lanthanum fluoride. The atomic layer deposition further coating including a carbon concentration of about 10,000 ppm or less, an oxygen concentration of about 10,000 ppm or less, and a sulfur concentration of about 500 ppm or less.

This application claims the benefit of priority to U.S. Provisional Patent Application Ser. No. 63/569,823 filed on Mar. 26, 2024, the content of which is relied upon and incorporated herein by reference in its entirety.

### FIELD

The present disclosure generally relates to coated optical components, more specifically, to optical components comprising a metal fluoride and plasma assisted atomic layer deposition coating for deep ultraviolet (DUV) applications, and to processes of producing such a coating. In embodiments, the metal fluoride and plasma assisted atomic layer deposition coating is an anti-reflective coating.

### TECHNICAL BACKGROUND

Anti-reflective (AR) coatings are useful in preventing undesirable reflection of light from a surface of an object. In general, light is more likely to reflect from a surface of an object when the light hits the surface at a high incident angle. Therefore, an object having a surface with a steep surface curvature is more likely to reflect light directed at it because at least some of the light will hit the surface at a relatively high incident angle.

Current physical vapor deposition (PVD) processes for AR coatings suffer from the inability to uniformly coat steep surface curvatures because these processes rely on a generally linear deposition of particles from a deposition source to a deposition target. To address this uniformity issue, complicated motion and screening steps need to be incorporated into the process. This increases the complexity of the process, the cost of the process, and the time needed to complete the process.

Accordingly, a need exists for new methods of depositing anti-reflective coatings.

### SUMMARY

For optical applications, such as optical lenses, reflection and/or absorption of light can be problematic. Reflection and/or absorption of light reduces the amount of light transmitted through an optical lens towards its desired target. A reduction in light transmitted can impair the resolution of an optical system that relies on an optical lens to collect and focus light. Such a reduction in resolution can impair the ability of the optical system to accurately image an object.

The reflection and/or absorption of light can be dependent on the wavelength(s) of light the optical system utilizes and the surface curvatures of the optical lens that are utilized to focus the wavelength(s) of light. For example, a high numerical aperture lens (i.e., an objective) for an optical inspection system may have a steep surface curvature for focusing light of a particular wavelength, or wavelength range. If light is reflected from such a steep surface, it can impair the ability of the inspection system to accurately image an object. Accurate imaging of an object is important in many applications, such as semiconductor wafer inspection systems. These systems need to be capable of accurately detecting any contamination (e.g., debris particles) on the surfaces of semiconductor wafers for quality control purposes.

Due to the importance of accurately imaging a surface, some optical inspection systems, like semiconductor inspection systems, utilize deep ultra-violet (DUV) laser-based light (i.e., light having a wavelength in the range of 157 nm and 193 nm to 266 nm) or light in the broadband spectrum (i.e., light having a wavelength in the range of 150 nm to 300 nm). These wavelengths are able to achieve higher resolutions than other wavelengths of light (e.g., visible light in the range of 400 nm to 700 nm). However, the intensity of light at these wavelengths is relatively low. Low intensity can be problematic because it can reduce the resolution capabilities of an inspection system. Therefore, one or more high numerical aperture lenses with steep surface curvatures may be needed to focus the light. Properly focusing DUV or broadband wavelengths increases the intensity of the light in a detection area, thereby achieving suitable detection resolutions.

The embodiments of the present disclosure comprise a coating for DUV or broadband wavelength based optical systems. But, in contrast to traditional coatings, the coatings disclosed herein are not formed by a PVD process. Instead, the coatings disclosed herein are formed by an atomic layer deposition (ALD) process. PVD coatings may be applied to optical components to provide increased anti-reflection properties. However, PVD coatings are difficult to apply to optical components with steeply curved surfaces. For example, the steeply curved surfaces create line of sight issues during the PVD coating process, which can lead to poor coating uniformity and/or necessitate complicated process modifications such as repositioning the PVD coating apparatus while the coating is applied to the optical component. The steeply curved surfaces may also cause the PVD coating to fall off the steeply curved surface during the coating process.

In the embodiments disclosed herein, the coatings are disposed on the optical components using an ALD process. Specifically, the ALD coatings disclosed herein comprise a metal fluoride based coating using a plasma as the fluorine source in order to reduce metal impurities in the coating. The plasma may be a sulfur hexafluoride. In some exemplary embodiments, the metal fluoride is lanthanum fluoride. The ALD coatings disclosed herein, as deposited using the processes disclosed herein, have enhanced uniformity and low surface roughness.

In embodiments, a coated optical component is described, the coated optical component comprising a substrate comprising at least one surface and an atomic layer deposition coating deposited on the surface of the substrate, the atomic layer deposition coating comprising a first layer of lanthanum fluoride. Furthermore, the atomic layer deposition coating comprises a carbon concentration of about 10,000 ppm or less, an oxygen concentration of about 10,000 ppm or less, and a sulfur concentration of about 500 ppm or less.

In embodiments, a process of coating an optical component with an atomic layer deposition coating is described, the process comprising converting a fluorine source into a sulfur hexafluoride-based plasma by generating a plasma of the fluorine source at a temperature from about 5° C. to about 20° C. while applying an electric current having a power from about 100 Watts to about 400 Watts and exposing a surface of a substrate to one cycle of an atomic layer deposition coating process in an atomic layer deposition chamber by (i) exposing the surface of the substrate to one or more pulses of a lanthanum-based metal precursor while heating the substrate to a temperature from about 100° C. to about 400° C. and (ii) exposing the surface of the substrate to one or more pulses of the sulfur hexafluoride-based plasma while heating the substrate to a temperature from about 100° C. to about 400° C.

Additional features and advantages of the metal fluoride and plasma assisted atomic layer deposition coating and the methods of producing the metal fluoride and plasma assisted atomic layer deposition coating described herein will be set forth in the detailed description that follows, and in part will be readily apparent to those skilled in the art from that description or recognized by practicing the embodiments described herein, including the detailed description that follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a partial view of an optical component coated with an ALD coating, according to the embodiments disclosed herein;

FIG. 2 schematically depicts a side view of an optical inspection system having a high numerical aperture objective lens, according to the embodiments disclosed herein;

FIG. 3A schematically depicts another partial view of an optical component coated with an ALD coating, according to the embodiments disclosed herein;

FIG. 3B schematically depicts another partial view of an optical component coated with an ALD coating, according to the embodiments disclosed herein;

FIG. 4 schematically depicts an ALD system for conducting an ALD coating process, according to the embodiments disclosed herein;

FIG. 5 schematically shows pulses applied to a substrate during one cycle of an ALD coating process, according to the embodiments disclosed herein;

FIG. 6 shows a plot of refractive index vs. wavelength for an ALD coating produced according to the embodiments disclosed herein and for a PVD coating;

FIG. 7A shows the thickness values of each layer of an exemplary ALD coating on a substrate and FIG. 7B shows a scanning electron microscope image of the exemplary ALD coating, according to the embodiments disclosed herein; and

FIG. 8 shows the reflectance of the exemplary coating of FIGS. 7A and 7B before and after a humidity test, according to the embodiments disclosed herein.

### DETAILED DESCRIPTION

As used herein, the term “substantially free” of a constituent refers to a composition that comprises less than 0.01 percent by weight the constituent. For example, an ALD coating that is substantially free of carbon comprises less than 0.01 percent by weight carbon.

The terms “microns” and “μm” are used interchangeably herein. The terms “nanometers” and “nm” are used interchangeably herein.

As used herein, the term “plasma” refers to a gas of ions that includes positive ions and electrons and that is generated from a gas-phase starting material through application of ionizing energy, such as energy in the form of heat or a voltage potential, or an electric current.

As used herein, the term “ppm” means parts per million on a molar basis and represents an atomic concentration. For example, a layer of LaF₃ with 1 ppm carbon includes 1 mole of carbon per million moles of LaF₃.

As used herein, the term “conformal coating” refers to a coating that conforms to the contours of the surfaces of an articles and has generally uniform thickness over all of the surfaces contacted by the coating.

As used herein, the term “anti-reflective (AR) coating” refers to a coating that has a reflectivity of less than 1% over a specific wavelength range, where “reflectivity” refers to the fraction of incident beam power being reflected and returned from a given surface. The reflectivity (R_{X}) of a surface can be expressed as Rx=Pᵣ/P₀, where P₀ is the incident beam power and Pᵣ is the power of the beam being returned from the surface.

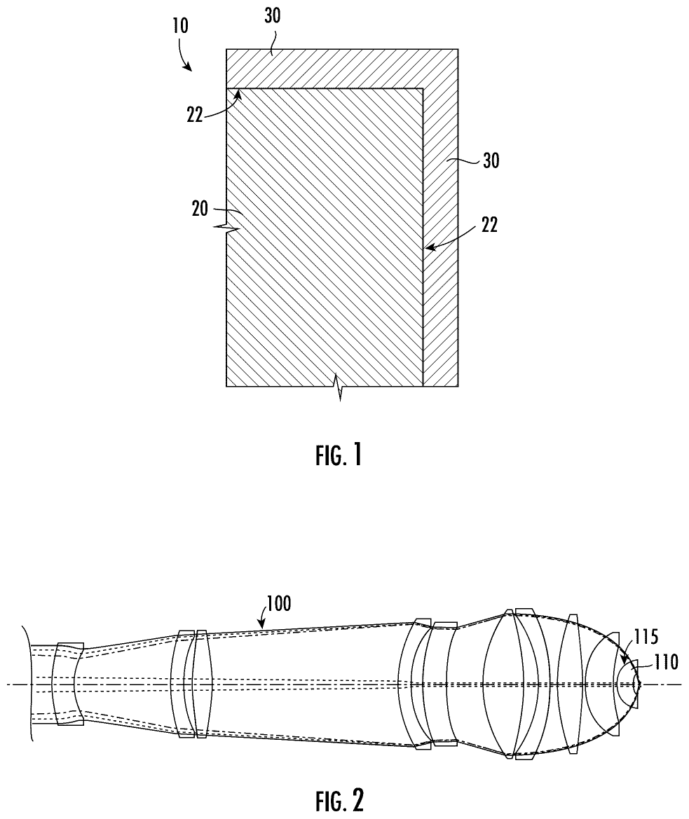

Reference will now be made in detail to various embodiments of the ALD coatings disclosed and the optical components coated thereby. With reference to FIG. 1, an exemplary coated optical component 10 is disclosed that comprises a substrate 20, which may be an optical component, and an ALD coating 30 applied to one or more surfaces 22 of substrate 20. In embodiments, substrate 20 may comprise, for example, a lens, window, objective, prism, beam splitter, filter, and/or mirror. ALD coating 30 may be a protective coating that provides a barrier on surface(s) 22 of substrate 20. In embodiments, ALD coating 30 may prevent or reduce deterioration and/or erosion of the material of substrate 20. As discussed further below, in embodiments, ALD coating 30 is an AR coating.

It is known in the art to coat optical components by physical vapor deposition (PVD) to extend the life of the optical components. For example, PVD coatings may be applied to such optical components as lenses, windows, objectives, prisms, beam splitters, filters, and/or mirrors to reduce surface deterioration and, thus, prolong the life of these components. PVD coatings may also be applied to provide anti-reflective properties to the optical components. Examples of PVD coatings include, but are not limited to, silica PVD coatings or a combination of a magnesium fluoride (MgF₂) PVD coating and a silica PVD coating. The total thickness of these PVD coatings are relatively thick to ensure the surface of the optical component is sealed by the PVD coating and so that no gaps or pinholes exist in the PVD coating. However, PVD coatings can be difficult to apply to optical components with steeply curved surfaces. For example, the steeply curved surfaces create line of sight issues during the PVD coating process, which can lead to poor coating uniformity and lack of conformality and/or necessitate complicated process modifications such as repositioning the PVD coating apparatus while the coating is applied to the optical component. The steeply curved surfaces may also cause the PVD coating to fall off the steeply curved surface during the coating process.

FIG. 2 shows an exemplary optical inspection system 100 for optical inspection using DUV or broadband spectral wavelengths. Optical inspection system 100 may comprise many different optical components including, for example, a high numerical aperture (NA) objective lens 110 with one or more surfaces 115 having a very steep curvature. As noted above, the steep curvature of surface(s) 115 may pose several problems during the PVD coating process, resulting in a non-uniform coating and/or complicated process modifications.

In contrast to the traditional PVD coatings, the ALD coatings disclosed herein may be applied to steeply curved surfaces (such as surface(s) 115) without the problems associated with the PVD coating process. As discussed further below, the ALD coating processes disclosed herein may provide a uniform ALD coating that is easy to apply, even to such steeply curved surfaces.

With reference again to FIG. 1, ALD coating 30 disclosed herein provides a protective barrier on surface(s) 22 of substrate 20 and/or ALD coating 30 provides anti-reflective properties to substrate 20. For example, ALD coating may prevent or reduce deterioration and/or erosion of the material of substrate 20. ALD coating 30 may comprise a metal fluoride, a metal oxide, a metalloid oxide, or combinations thereof. Additionally or alternatively, ALD coating 30 may comprise a silica, an alumina, or combinations of these components. In embodiments, ALD coating 30 comprises at least a high refractive index fluoride such as, for example, lanthanum fluoride (LaF₃) and/or gadolinium fluoride (GdF₃). In yet some additional embodiments, ALD coating 30 comprises a high refractive index metal fluoride and a low refractive index metal fluoride. In embodiments, the high refractive index metal fluoride comprises LaF₃ and/or GdF₃ and the low refractive index metal fluoride comprises magnesium fluoride (MgF₂) and/or aluminum fluoride (AlF₃). The inclusion of LaF₃ in ALD coating 30 is advantageous due to its relatively large band gap, high refractive index, high transmittance, and chemical and mechanical stability at, for example, wavelengths within the DUV range. In particular, at DUV wavelengths from 193 nm to 266 nm, LaF₃ has a band gap of 6.04 electronvolt (eV). The inclusion of MgF₂ in ALD coating 30 is advantageous due to its low refractive index, high transmittance, and chemical and mechanical stability at, for example, wavelengths within the DUV range. In some exemplary embodiments, as also discussed below, ALD coating 30 comprises alternating layers of LaF₃ and MgF₂.

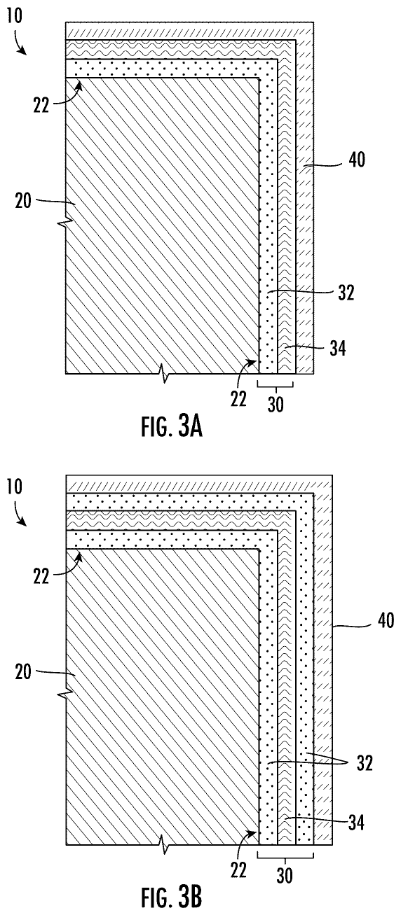

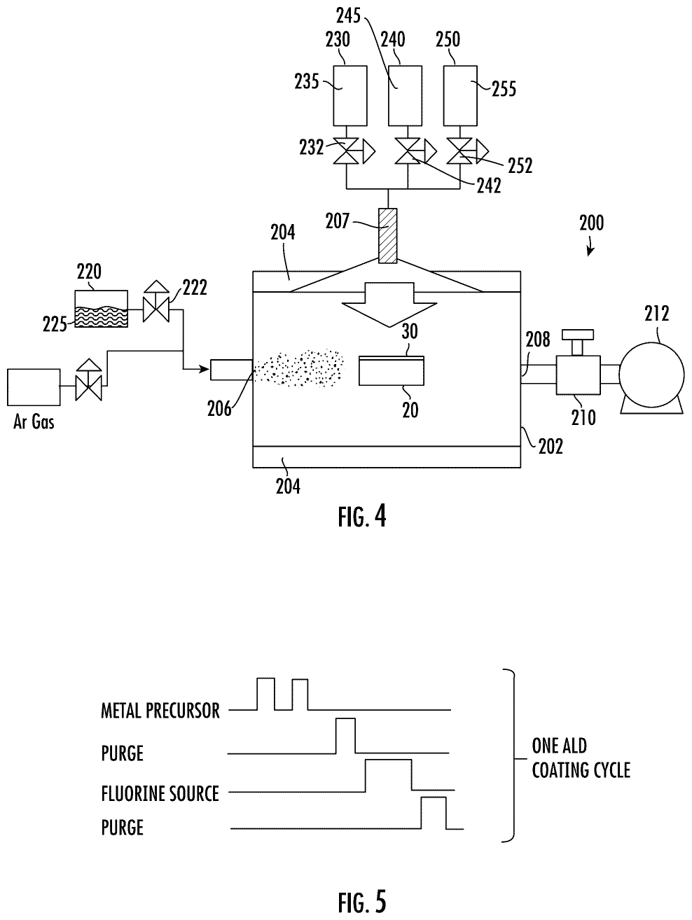

As shown in FIG. 3A, ALD coating 30 may comprise a plurality of layers including a first layer 32 and a second layer 34. Each of the first and second layers 32, 34 may be applied to substrate 20 through an ALD process, as discussed further below. Second layer 34 may comprise a different material from that of first layer 32, such as a different metal fluoride. Furthermore, second layer 34 may be directly attached to first layer 32 without any intervening coatings or other materials disposed between the layers. It is also noted that first layer 32 may be directly attached to substrate 20 without any intervening coatings or materials disposed between first layer 32 and substrate 20. In other embodiments, second layer 34 is directly attached to substrate 20 without any intervening coatings or materials disposed between second layer 34 and substrate 20. Although FIG. 3A only depicts ALD coating 30 as comprising first layer 32 and second layer 34, it is contemplated herein that ALD coating 30 may comprise more layers. For example, ALD coating 30 may comprise 2 or more, or 3 or more, or 4 or more, or 5 or more, or 6 or more, or 7 or more, or 8 or more, or 9 or more, or 10 or more of each of first layer 32 and second layer 34. One or more of the multiple layers of first layer 32 and second layer 34 may have a different material (such as a different metal fluoride) from one or more of the other layers. In some embodiments, ALD coating 30 comprises alternating layers of first layer 32 and second layer 34. It is also contemplated herein that ALD coating 30 may comprise one or more additional layers in addition to first layer 32 and second layer 34.

In some embodiments, first layer 32 comprises a metal fluoride with a relatively low refractive index and second layer 34 comprises a metal fluoride with a relatively high refractive index such that the refractive index of second layer 34 is higher than the refractive index of first layer 32. For example, the refractive index of first layer 32 may be from about 1.30 to about 1.60, or about 1.32 to about 1.58, or about 1.34 to about 1.56, or about 1.36 to about 1.54, or about 1.38 to about 1.52, or about 1.40 to about 1.50, or about 1.42 to about 1.48, or about 1.44 to about 1.46 (or any range encompassing these endpoints) at a wavelength of 193 nm. Furthermore, the refractive index of second layer 34 may be from about 1.65 to about 1.75, or about 1.66 to about 1.74, or about 1.67 to about 1.73, or about 1.68 to about 1.72, or about 1.69 to about 1.71, or about 1.70 to about 1.75 (or any range encompassing these endpoints) at a wavelength of 193 nm. In some embodiments, first layer 32 comprises MgF₂ with a refractive index of 1.43 at 193 nm and second layer 34 comprises LaF₃ with a refractive index of 1.72 at 193 nm.

As also discussed below, each of the plurality of layers (e.g., first layer 32, second layer 34) may comprise a different material such as a different metal fluoride. In some embodiments, first layer 32 comprises MgF₂ and second layer 34 comprises LaF₃ such that ALD coating 30 comprises alternating layers of MgF₂ and LaF₃. FIG. 3A shows one exemplary embodiment in which ALD coating 30 comprises one layer of each of first layer 32 and second layer 34. FIG. 3B shows another exemplary embodiment in which ALD coating 30 comprises two layers of first layer 32 and one layer of second layer 34 such that the first and second layers 32, 34 are alternating. In some exemplary embodiments of FIG. 3B, first layer 32 comprises MgF₂ (with a refractive index of 1.43 at 193 nm) and second layer 34 comprises LaF₃ (with a refractive index of 1.72 at 193 nm).

Each individual layer (first layer 32, second layer 34) is formed by the ALD layer-by-layer deposition of the material of that individual layer. More specifically, one ALD coating cycle, as also discussed below, deposits one deposition layer of material. The ALD coating cycle is then repeated many times to form each of first layer 32 and second layer 34. In one exemplary embodiment, one ALD coating cycle applies a deposition layer of MgF₂ on substrate 20, and that ALD coating cycle is then repeated 300 times to form first layer 32 on substrate 20. Next, in this exemplary embodiment, one ALD coating cycle applies a deposition layer of LaF₃ on first layer 32, and that ALD coating cycle is then repeated 500 times to form second layer 34 on first layer 32.

In embodiments, the deposition layer formed by each ALD coating cycle forms a monolayer of material with a thickness comparable to a size of a single molecule of the ALD coating material. In the embodiments disclosed herein, each ALD coating cycle may be repeated 50 or more times, or 100 or more times, or 150 or more times, or 200 or more times, or 250 or more times, or 300 or more times, or 350 or more times, or 400 or more times, or 450 or more times, or 500 or more times, or 550 or more times, or 600 or more times, or 650 or more times, or 700 or more times, or 750 or more times, or 800 or more times, or 850 or more times, or 900 or more times, or 950 or more times, or 1000 or more times, or any range encompassing these endpoints, in order to produce each layer of the plurality of layers (e.g., first layer 32, second layer 34).

Each deposition layer formed by one ALD coating cycle may have a thickness of about 0.001 nm or greater, or about 0.005 nm or greater, or about 0.008 nm or greater, or about 0.010 nm or greater, or about 0.020 nm or greater, or about 0.030 nm or greater, or about 0.040 nm or greater, or about 0.050 nm or greater, or about 0.060 nm or greater, or about 0.070 nm or greater, or about 0.080 nm or greater, or about 0.090 nm or greater, or about 0.100 nm or greater. Additionally or alternatively, each deposition layer formed by one ALD coating cycle may have a thickness of about 0.100 nm or less, or about 0.090 nm or less, or about 0.080 nm or less, or about 0.070 nm or less, or about 0.060 nm or less, or about 0.050 nm or less, or about 0.040 nm or less, or about 0.030 nm or less, or about 0.020 nm or less, or about 0.010 nm or less, or about 0.008 nm or less, or about 0.005 nm or less, or about 0.001 nm or less. In some embodiments, the thickness is in a range from about 0.001 nm to about 0.100 nm, or about 0.005 nm to about 0.090 nm, or about 0.005 nm to about 0.080 nm, or about 0.008 nm to about 0.070 nm, or about 0.008 nm to about 0.060 nm, or about 0.010 nm to about 0.050 nm, or about 0.020 nm to about 0.040 nm, or about 0.020 nm to about 0.030 nm, or any range encompassing these endpoints.

Each layer of the plurality of layers (e.g., first layer 32, second layer 34) of ALD coating 30, formed by the layer-by-deposition of the ALD coating cycles, may have a thickness of about 2 nm or greater, or about 5 nm or greater, or about 10 nm or greater, or about 15 nm or greater, or about 20 nm or greater, or about 25 nm or greater, or about 30 nm or greater, or about 35 nm or greater, or about 40 nm or greater. Additionally or alternatively, each layer of the plurality of layers (e.g., first layer 32, second layer 34) of ALD coating 30 may have a thickness of about 40 nm or less, or about 35 nm or less, or about 30 nm or less, or about 25 nm or less, or about 20 nm or less, or about 15 nm or less, or about 10 nm or less, or about 5 nm or less or about 2 nm or less. In some embodiments, the thickness is in a range from about 2 nm to about 40 nm, or about 5 nm to about 35 nm, or about 10 nm to about 30 nm, or about 15 nm to about 25 nm, or about 20 nm to about 25 nm, or any range encompassing these endpoints.

Coated optical component 10 may also comprise a capping layer 40 disposed on and outward of ALD coating 30. Capping layer 40 may comprise, for example, silica (SiO₂). In embodiments, the material of capping layer 40 is doped with one or more dopants such as, for example, fluorine. Capping layer 40 may provide many benefits to ALD coating 30 including improved environmental stability and laser exposure durability.

Substrate 20 may comprise any material that is capable of supporting ALD coating 30. In some embodiments, substrate 20 is a substrate comprised of, for example, glass, glass-ceramic, or ceramic such as, for example, silicate glass, soda lime glass, an alkali aluminosilicate glass, an alkali containing borosilicate glass, an alkali aluminoborosilicate glass, and/or fused quartz. Exemplary glass substrates include, but are not limited to, HPFS® fused silica sold by Corning Incorporated of Corning, New York under glass codes 7980, 7979, and 8655, and EAGLE XG® boro-aluminosilicate glass also sold by Corning Incorporated of Corning, New York. Other glass substrates include, but are not limited to, Lotus™ NXT glass, Iris™ glass, WILLOW® glass, GORILLA® glass, VALOR® glass, or PYREX® glass sold by Corning Incorporated of Corning, New York. In some embodiments, the glass or glass ceramic has 50 wt. % or more, 60 wt. % or more, 70 wt. % or more, 80 wt. % or more, 90 wt. % or more, or 95 wt. % or more silica content by weight on an oxide basis. Exemplary glass ceramics include, for example, lithium disilicate, nepheline, beta-spodumene, and beta-quartz. Exemplary commercially available materials include, for example, Macor® and Pyroceram® sold by Corning Incorporated of Corning, New York. In embodiments, substrate 20 is a glass, glass-ceramic, or ceramic comprised of a metal, a metal fluoride (e.g., calcium fluoride (CaF₂), magnesium fluoride (MgF₂)), a metal alloy, and/or a metalloid. In some exemplary embodiments, substrate 20 is comprised of an aluminum metal, an aluminum alloy, silicon, or combinations of these materials. In some exemplary embodiments, substrate 20 is comprised of silicon.

As noted above, substrate 20 may have one or more surfaces 22 with a steep curvature. The steepness of surfaces 22 may each have a steepness value in a range from 0.5 to 1.0, wherein the steepness value is equal to the radius of curvature of surface 22 divided by the clear aperture of coated optical component 10, as shown in the following equation:

$$S = R / \#$$

where S is the steepness value, R is the radius of curvature of surface 22, and # is the clear aperture of coated optical component 10. A steepness value in the range from 0.5 to 1.0 facilitates focusing of DUV and/or broadband spectrum light to an intensity suitable for accurate detection resolutions in an optical inspection system (such as optical inspection system 100). A “clear aperture” is the diameter of an optical component through which light passes during the intended use of the optical component. In some cases, the “clear aperture” may be the diameter of the entire optical component measured between opposing points on the peripheral edge of the optical component. In some cases, the “clear aperture” may be less than the diameter of the entire optical component, for example, if the optical component is surrounded by a frame that ends over a peripheral edge of the optical component. For non-circular optical components, the “clear aperture” is the maximum outer cross-sectional dimension of the optical component through which light passes during the intended use of the optical component.

In embodiments, substrate 20 is in direct contact with ALD coating 30 without any intervening coatings or other materials disposed between substrate 20 and ALD coating 30.

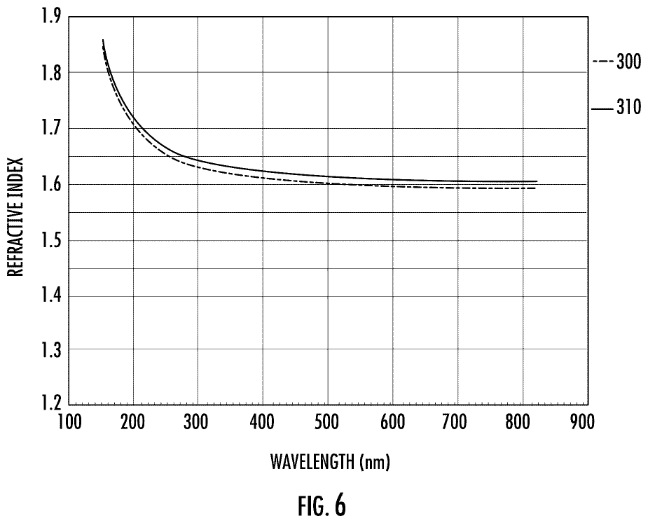

The coating of substrate 20 with ALD coating 30 may be conducted using an ALD coating system 200, as shown schematically in FIG. 4. ALD coating system 200 comprises an ALD chamber 202 that supports and houses substrate 20 during the coating process. ALD chamber 202 may be a sealed chamber that is heated, in embodiments, by one or more heating devices 204, which are in thermal communication with ALD chamber 202. As also shown in FIG. 4, ALD chamber 202 comprises an inlet 206 and an outlet 208. Inlet 206 is configured to introduce various constituents used in the ALD coating process, as discussed further below, into ALD chamber 202. Outlet 208 is configured to remove the various constituents from ALD chamber 202. In embodiments, outlet 208 is in fluid communication with a throttle vale 210 that is disposed downstream of ALD chamber 202. Throttle valve 210 is configured to control the flow of constituents out of ALD chamber 202. ALD coating system 200 further comprises a vacuum pump 212 coupled to outlet 208 and disposed downstream of throttle valve 210. Vacuum pump 212 is configured to create a vacuum within ALD chamber 202 to draw ALD reaction constituents into ALD chamber 202 and to pull unreacted constituents, reaction products, inert gases, and other materials out of ALD chamber 202.

ALD coating system 200 also comprises one or more sources of reaction constituents in fluid communication with inlet 208. In particular, ALD coating system 200 may comprise a metal precursor reservoir 220 that houses a metal precursor 225 and that is fluid communication with inlet 208. One or more inert gases, such as argon, may also be in fluid communication with inlet 208 to help transport metal precursor 225 into ALD chamber 202. A metal precursor control valve 222 may be disposed between metal precursor reservoir 220 and ALD chamber 202 and operable to control the flow rate of metal precursor 225 into ALD chamber 202. ALD coating system 200 may also comprise a fluorine reservoir 230 that houses a fluorine source 235, an oxygen reservoir 240 that houses an oxygen source 245, and an inert gas reservoir 250 that houses one or more inert gases 255. Fluorine source 235, oxygen source 245, and/or inert gases 255 may flow into ALD chamber 202 through an inductively coupled plasma (ICP) reactor 207. A fluorine source control valve 232 may be disposed between fluorine reservoir 230 and reactor 207 and operable to control the flow rate of fluorine source 235 into reactor 207. An oxygen source control valve 242 may be disposed between oxygen reservoir 240 and reactor 207 and operable to control the flow rate of oxygen source 245 into reactor 207. An inert gas source control valve 252 may be disposed between inert gas reservoir 250 and reactor 207 and operable to control the flow rate of inert gases 255 into reactor 207.

Metal precursor 225 may be in vapor, solid, liquid, or atomized liquid form. Metal precursor 225 may comprise one or more of a lanthanum precursor, a gadolinium precursor, an aluminum precursor, a magnesium precursor, a lithium precursor, and a calcium precursor, depending on the desired metal component of ALD coating 30. In some exemplary embodiments, when ALD coating 30 comprises LaF₃, metal precursor 225 comprises lanthanum metallocene (e.g., La(isopropylcyclopentadienyl)₂(isopropylamidinate)), tris(N,N′-diisopropylformamidinato)lanthanum, (2,2,6,6-tetramethyl-3,5-heptanedione)lanthanum, Tris[N,N-bis(trimethylsilyl)amide]lanthanum(III), Tris(tetramethylcyclopentadienyl)lanthanum(III), LANA™ brand lanthanum precursor from Air Liquide, and combinations thereof.

Additionally or alternatively, metal precursor 225 may comprise gadolinium tris(N,N′-isopropylacetamidinate), tris(isopropyl-cyclopentadienyl)gadolinium(III) (Gd(iPrCp)₃), tris(OCMe₂CH₂OMe) gadolinium(III) (Gd(mmp)₃), tris(2,3-dimethyl-2-butoxy) gadolinium(III) (Gd(DMB)₃), tris(2,2,6,6-tetramethyl-3,5-heptanedionato) gadolinium(III) (Gd(thd)₃), GANBETTA™ brand gadolinium precursor available from Air Liquide, GAUDI™ brand gadolinium precursor available from Air Liquide, and combinations thereof.

Additionally or alternatively, metal precursor 225 may comprise a metal ligand complex comprising aluminum, Trimethylamine (TMA), dimethylaluminum isopropoxide (DMAI), dimethylaluminum hydride: dimethylethylamine, ethylpiperidine: dimethylaluminum hydride, dimethylaluminum chloride (DMAC), aluminum hexafluoroacetylacetonate (Al(hfac)₃), tri-i-butylaluminum (Al(i-Bu)₃), tris(2,2,6,6-tetramethyl-3,5-heptanedionato)aluminum (Al(TMHD)₃, a metal ligand complex comprising magnesium, bis(ethylcyclopentadienyl)magnesium, bis(cyclopentadienyl)magnesium(II), bis(2,2,6,6-tetramethyl-3,5-heptanedionato)magnesium, bis(N,N′-di-sec-butylacetamidinato)magnesium, bis(pentamethylcyclopentadienyl)magnesium, Ca(2,2,6,6-tetramethyl-3,5-heptanedionato)₂, Bis(N,N′-diisopropylformamidinato)calcium(II), bis(N,N′-diisopropylacetamidinato)calcium(II), [Ca₃(2,2,6,6-tetramethyl-3,5-heptanedionate)₆], Ca(1,2,4-triisopropylcyclopentadienyl)₂], lithium tert-butoxide, lithium 2,2,6,6-tetramethyl-3,5-heptanedionate, and combinations thereof.

Fluorine source 235 may be derived from a fluorine-containing precursor selected from the group consisting of sulfur hexafluoride (SF₆), nitrogen trifluoride (NF₃), ammonium fluoride (NH₄F), trifluoroiodomethane (CF₃I), hydrogen fluoride (HF), and combinations thereof. In embodiments, the ALD process is a plasma-assisted ALD process in which the fluorine source is a plasma fluorine source derived from a fluorine-containing precursor or a fluorine-containing precursor and an argon (Ar) plasma. The fluorine source may comprise, for example, a plasma comprising SF₆, SF₆ and Ar (SF₆/Ar), or NF₃ and Ar (NF₃/Ar). In embodiments, the fluorine source may be derived from one or more organic fluorine sources, such as but not limited to hexafluoroacetylacetone or other fluorine-containing organic compounds.

In some exemplary embodiments, fluorine source 235 comprises SF₆ or a plasma derived from SF₆ (i.e., an SF₆-based plasma). In embodiments, fluorine source 235 may comprise, consist of, or consist essentially of an SF₆-based fluorine source, such as SF₆ or an SF₆-based plasma. In embodiments, fluorine source 235 may comprise, consist of, or consist essentially of a plasma derived from SF₆ and argon (i.e., an SF₆/Ar plasma) and/or another inert gas. When fluorine source 235 comprises an SF₆/Ar plasma, a flow rate ratio of the Ar to SF₆ may be from 0.1:1 to 10:1, from 0.1:1 to 5:1, from 0.1:1 to 2:1, from 0.5:1 to 10:1, from 0.5:1 to 5:1, from 0.5:1 to 2:1, from 1:1 to 10:1, from 1:1 to 5:1, from 1:1 to 2:1, from 2:1 to 10:1, from 2:1 to 5:1, or about 2:1, wherein the flow rate is a volumetric flow rate expressed in units of sccm (standard cubic centimeters per minute). SF₆ is advantageous as a fluorine source in that it is safer to use than, for example, HF, which is dangerous to handle and highly corrosive, particularly when contacted with water.

Oxygen source 245 can include water (H₂O), H₂O plasma, ozone (O₃), O₃ plasma, oxygen (O₂), O₂ plasma, hydrogen peroxide (H₂O₂), H₂O₂ plasma, other oxygen-containing gases, other oxygen-containing liquids, or combinations of these. Oxygen source 245 may be in a liquid state, gaseous state, or plasma state.

Inert gases 255 may include non-reactive gases, such as but not limited to noble gases (e.g., Ar, He, Ne, etc.). Inert gases 255 may act as a carrier for transporting the precursors into ALD chamber 202.

The ALD coating process may begin with the placement of substrate 20 in ALD chamber 202. During the ALD coating process, substrate 20 is exposed to alternating pulses of one or more precursor compounds (e.g., metal precursor 225, fluorine source 235, oxygen source 245) in a single ALD coating cycle, where exposure to the alternating pulses of the precursor compounds causes layer-by-layer deposition of ALD coating 30 on the surface(s) of substrate 20, with each layer having a thickness comparable to a size of a single molecule of the ALD coating material (e.g. monolayer coverage of the surface(s)). The ALD coating process can enable coating of all surfaces of substrate 20 in a single deposition run with atomic layer precision.

In embodiments the ALD coating process may be a direct reduction ALD process, during which metal precursor 225 is deposited onto surface(s) 22 of substrate 20 and then directly reduced using fluorine source 235, which acts as a reducing agent. In particular, surface(s) 22 of substrate 20 may be exposed, within ALD chamber 202, to alternating pulses of metal precursor 225 and fluorine source 235. The pulse(s) of metal precursor 225 may include metal precursor 225 along with one or more inert gases 255, which act as a carrier for transporting metal precursor 225 into ALD chamber 202.

FIG. 5 shows one exemplary cycle of an ALD coating process cycle in which substrate 20 is exposed to one or more pulses of metal precursor 225 followed by a first purge. After the first purge, substrate 20 is exposed to one or more pulses of fluorine source 235 followed by a second purge. The cycle shown in FIG. 5 may produce one deposition layer of ALD coating 30 (the deposition layer having the monolayer thickness, in embodiments). The cycle may be repeated a plurality of times to produce the layer-by-layer deposition of ALD coating 30 (and, thus, to produce the plurality of layers 32, 34). Although FIG. 5 shows two pulses of metal precursor 225 in the one exemplary cycle, it is noted that substrate 20 may be exposed to more or less pulses of metal precursor 225 per cycle. In embodiments, substrate 20 may be exposed to 1 to 5 pulses of metal precursor 225 during one cycle of the ALD coating process, or 1 to 4 pulses, or 1 to 3 pulses, or 2 to 4 pulses, or 2 to 3 pulses. Similarly, although FIG. 5 only shows one pulse of fluorine source 235 in the ALD coating process cycle, it is noted that substrate 20 may be exposed to more pulses of fluorine source 235 per cycle. In embodiments, substrate 20 may be exposed to 1 to 5 pulses of fluorine source 235 during one cycle of the ALD coating process, or 1 to 4 pulses, or 1 to 3 pulses, or 2 to 4 pulses, or 2 to 3 pulses.

In embodiments, metal precursor 225 is heated to a temperature from about 95° C. to about 200° C., or about 100° C. to about 190° C., or about 110° C. to about 180° C., or about 120° C. to about 170° C., or about 130° C. to about 160° C., or about 140° C. to about 150° C., or any range encompassing these endpoints prior to introducing metal precursor 225 into ALD chamber 202. Substrate 20 may be exposed to the one or more pulses of metal precursor 225 within ALD chamber 202 during each ALD coating cycle. The pulse(s) of metal precursor 225 for each ALD coating cycle may be for a sufficient time duration to enable metal precursor 225 to react with at least at least 90%, at least 95%, at least 98%, at least 99%, or at least 99.9% of the reaction sites on surface 22 of substrate 20 (or on the outer surface of the previously applied coating layer). In embodiments, each pulse of metal precursor 225 within a single cycle of the ALD coating process may be for a duration from about 0.01 seconds to about 10 seconds, or about 0.10 seconds to about 9 seconds, or about 0.50 seconds to about 8 seconds, or about 1 second to about 7 seconds, or about 2 seconds to about 6 seconds, or about 3 seconds to about 5 seconds, or about 4 seconds to about 10 seconds, or any combination of these ranges. As an example, in some embodiments, substrate 20 may be exposed to 2 pulses of metal precursor 225 for each ALD coating process cycle, wherein each pulse has a duration of about 0.50 seconds. Factors influencing the pulse duration of metal precursor 225 include the vapor pressure of the precursor, the flow rate of the precursor, the reactivity of the precursor with surface 22 of substrate 20, the volume of ALD chamber 202, and the dimensions of substrate 20. In embodiments, the pulse duration of metal precursor 225 is for a sufficient time duration to produce conformal coverage (thus producing a conformal coating) over at least 90%, or at least 95%, or at least 98%, or at least 99%, or at least 99.9% over the areas of substrate 20 to be coated.

As shown in FIG. 5, during the same ALD coating cycle and after exposure of substrate 20 to the pulse(s) of metal precursor 225, ALD chamber 202 may then be purged with inert gases 255 to remove any residual metal precursor 225 from ALD chamber 202 before continuing with the ALD process.

The ALD coating process may further include, after purging ALD chamber 202 with inert gases 255 and during the same ALD coating cycle, exposing substrate 20 having the layer of metal precursor 225 adsorbed thereon to the one or more pulses of fluorine source 235. The pulse(s) of fluorine source 235 for each ALD coating cycle may be for a sufficient time duration to enable fluorine source 235 to react with at least 95%, at least 98%, at least 99%, or at least 99.9% of the reaction sites on the metal precursor 225 disposed on substrate 20. In embodiments, each pulse of fluorine source 235 within a single cycle of the ALD coating process may be for a duration from about 0.01 seconds to about 30 seconds, or about 0.10 seconds to about 28 seconds, or about 0.50 seconds to about 25 seconds, or about 1 second to about 22 seconds, or about 2 seconds to about 20 seconds, or about 3 seconds to about 15 seconds, or about 4 seconds to about 10 seconds, or about 5 seconds to about 10 seconds, or any combination of these ranges. In embodiments, each pulse of fluorine source 235 may be longer in duration than each pulse of metal precursor 225 during the same ALD coating cycle.

As also shown in FIG. 5, during the same ALD coating cycle and after exposure of substrate 20 to the pulse(s) of fluorine source 235, ALD chamber 202 may again be purged with inert gases 255 to remove any residual fluorine source 235 from ALD chamber 202 before continuing with the ALD process.

The ALD coating cycle depicted in FIG. 5 may be repeated a plurality of times to build up the thickness of the ALD coating. Each iteration of the ALD coating cycle may add another molecular layer of the ALD coating material to ALD coating 30 in order to form each of the plurality of layers (e.g., first layer 32, second layer 34). The thickness of each layer (first layer 32, second layer 34) and, thus, the thickness of ALD coating 30 may be controlled by controlling the number of iterations of the ALD coating cycles, thus, controlling the number of molecular layers of ALD coating material in ALD coating 30.

In some exemplary embodiments, as disclosed above, the ALD coating process comprises using at least an La-based metal precursor as metal precursor 225 and an SF₆—Ar plasma mixture as fluorine source 235 to produce an ALD coating 30 that comprises at least LaF₃. Furthermore, in some exemplary embodiments, as also disclosed above, the ALD coating process comprises using an Mg-based metal precursor as metal precursor 225 and an SF₆—Ar plasma mixture as fluorine source 235 to produce a first layer 32 of ALD coating 30 and the ALD coating process comprises using an La-based metal precursor as metal precursor 225 and an SF₆—Ar plasma mixture as fluorine source 235 to produce a second layer 34 of ALD coating 30.

As discussed above, heating device(s) 204 may heat ALD chamber 202 during the ALD coating process. Therefore, heating device(s) 204 may heat ALD chamber 202 during the pulsing of metal precursor 225 and/or fluorine source 235. In embodiments, the temperature of ALD chamber 202, during the pulsing of metal precursor source 225 and/or during the pulsing of fluorine source 235, is heated to a processing temperature that is within a range from about 100° C. to about 400° C., or about 125° C. to about 375° C., or about 150° C. to about 350° C., or about 175° C. to about 325° C., or about 200° C. to about 300° C., or about 225° C. to about 275° C., or about 250° C. to about 300° C., or any range encompassing these endpoints. When the temperature is too low, such as below 100° C., more impurities are formed in the deposited ALD coating 30. However, when the temperature is too high, such as above 400° C. or above 300° C., the deposited metal precursor begins to etch, which slows the growth rate of ALD coating 30.

In embodiments in which fluorine source 235 is plasma based, fluorine source 235 may be converted into a plasma by heating the material and subjecting the material to an electric current, voltage, or a strong electromagnetic field. In particular, within reactor 207 of ALD coating system 200, as shown in FIG. 4, fluorine source 235 may be exposed to an ICP to convert fluorine source 235 to a plasma. The ICP generates fluorine containing radicals or ions in reactor 207, which causes fluorine source 235 to be subjected to an electric current that converts the material into a plasma. In embodiments, converting the material into a plasma may comprise heating the material to a temperature from about 5° C. to about 20° C., or about 10° C. to about 15° C., or about 12° C. to about 18° C. (or any range encompassing these endpoints) and applying an electric current having a power from about 100 Watts (W) to about 400 W, or about 125 W to about 375 W, or about 150 W to about 350 W, or about 175 W to about 325 W, or about 200 W to about 300 W, or about 225 W to about 375 W, or about 250 W to about 300 W (or any range encompassing these endpoints).

Reactor 207 may comprise a remote plasma generator because fluorine source 235 is converted to a plasma remote from and outside of ALD chamber 202. In other embodiments, fluorine source 235 may be converted to a plasma within ALD chamber 202.

The ALD process disclosed herein may also comprise cleaning surface(s) of substrate 20 before depositing ALD coating 30 thereon. Furthermore, the ALD process disclosed herein may comprise, after exposing substrate 20 to the pulse(s) of metal precursor 225 and the first purge (as shown in FIG. 5), exposing substrate 20 to one or more pulse(s) of oxygen source 245. Exposing substrate 20 to such an oxygen-containing pulse may oxidate the metal precursor 225 absorbed on substrate 20, to form the metal oxide on surface(s) 22 of substrate 20. The pulse(s) of oxygen source 245 for each ALD coating process cycle may be for a sufficient time duration to enable oxygen source 245 to react with at least 95%, at least 98%, at least 99%, or at least 99.9% of the reaction sites on the metal precursor 225 disposed on substrate 20. In embodiments, each pulse of oxygen source 245 within a single cycle of the ALD coating process may be for a duration from about 0.01 seconds to about 10 seconds, or about 0.10 seconds to about 9 seconds, or about 0.50 seconds to about 8 seconds, or about 1 second to about 7 seconds, or about 2 seconds to about 6 seconds, or about 3 seconds to about 5 seconds, or about 4 seconds to about 10 seconds, or any combination of these ranges. After exposure of substrate 20 to the pulse(s) of oxygen source 245, ALD chamber 202 may then be purged with inert gases 255 to remove any residual oxygen source 245 from ALD chamber 202 before continuing with the ALD process.

In the embodiments disclosed herein, ALD coating 30 may have a total thickness sufficient to cover the surface(s) 22 of substrate 20 without substantial exposure of the surface(s) of substrate 20 to the atmosphere within the coated area. In embodiments, ALD coating 30 may comprise a total thickness (which includes the combined thickness of each of the plurality of layers 32, 34) of about 200 nm or less, or about 190 nm or less, or about 180 nm or less, or about 170 nm or less, or about 160 nm or less, or about 150 nm or less or about 140 nm or less, or about 130 nm or less, or about 120 nm or less, or about 110 nm or less, or about 100 nm or less, or about 90 nm or less or about 80 nm or less, or about 70 nm or less, or about 60 nm or less, or about 50 nm or less, or about 40 nm or less, or about 30 nm or less, or about 20 nm or less. Additionally or alternatively, ALD coating 30 may comprise a total thickness of about 20 nm or greater, or about 30 nm or greater, or about 40 nm or greater, or about 50 nm or greater, or about 60 nm or greater, or about 70 nm or greater, or about 80 nm or greater, or about 90 nm or greater, or about 100 nm or greater, or about 110 nm or greater, or about 120 nm or greater, or about 130 nm or greater, or about 140 nm or greater, or about 150 nm or greater, or about 160 nm or greater, or about 170 nm or greater, or about 180 nm or greater, or about 190 nm or greater, or about 200 nm or greater. In some exemplary embodiments, the total thickness is in a range from about 20 nm to about 200 nm, or about 30 nm to about 190 nm, or about 40 nm to about 180 nm, or about 50 nm to about 170 nm, or about 60 nm to about 160 nm, or about 70 nm to about 150 nm, or about 80 nm to about 140 nm, or about 90 nm to about 130 nm, or about 100 nm to about 120 nm, or about 100 nm to about 110, or any range encompassing these endpoints.

ALD coating 30, as disclosed herein, is an atomically dense, pin-hole-free, protective coating. The ALD coating processes disclosed herein can advantageously produce such coatings without the costly and time-consuming processes involved for PVD coatings. Thus, the processes disclosed herein can reduce coating stress and increase the lifetime of the coated optical components.

In embodiments, ALD coating 30 produced according to the processes disclosed herein comprises a reduced surface roughness. In particular, surface 22 of substrate 20 coated with ALD coating 30 may comprise a surface roughness (Ra) of about 1.5 nm or less, or about 1.25 nm or less, or about 1.00 nm or less, or about 0.75 nm or less, or about 0.60 nm or less, or about 0.50 nm or less, or about 0.40 nm or less, or about 0.30 nm or less, or about 0.20 nm or less, or about 0.10 nm or less, or about 0.05 nm or less, or about 0.01 nm or less, or any range encompassing these endpoints. Ra surface roughness is determined by measuring a 2 micron by 2 micron square area with an atomic force microscope having a resolution of 512×512 pixels.

ALD coating 30 may be a conformal coating having a uniform thickness across all coated surfaces. In embodiments, ALD coating 30 may have a thickness that varies by less than or equal to 5%, less than or equal to 4%, less than or equal to 3%, less than or equal to 2%, less than or equal to 1%, or even less than or equal to 0.5% across the entirety of the coated area from an average thickness of ALD coating 30. The average thickness of ALD coating 30 is the thickness of ALD coating 30 averaged over all of the surface area of the surface(s) 22 in contact with ALD coating 30. A “thickness variation” for a layer of coating or a coating is calculated using the following equation:

$$T = SD / A \times 100$$

where T equals the thickness variation, SD equals to the standard deviation of a representative set of thickness measurements, and A equals the average value of the representative set thickness measurements. A thickness variation is defined by the thickness variation for the entire surface area of a layer of coating or of a coating over a surface bound by a peripheral edge represented by a set of thickness measurements. In embodiments, ALD coating 30 may cover the entirety of surface 22 bounded by the peripheral edges of substrate 20. In such embodiments, the thickness variation of ALD coating 30 is defined by the thickness variation of ALD coating 30 disposed over the entirety of surface 22. The thickness values disclosed herein are measured by a spectroscopic ellipsometer. A representative set of thickness measurements includes at least three measurements. For purposes of selecting points for thickness measurements, the points should be spaced apart to provide a representation of the entire film being measured and should not all be located in a single region of the coating (i.e., not all at the edge of the coating).

In one exemplary example, a 150 millimeter (mm) diameter substrate comprised of Si was coated with ALD coating 30 using the processes disclosed herein. In this exemplary example, ALD coating 30 comprises one layer of LaF₃ with an average thickness of 31.8 nm. The process to produce this exemplary example includes first exposing the substrate to 3 separate pulses of an La-based metal precursor at a temperature of 160° C. Each pulse was for a duration of 0.5 seconds. Next, the substrate was purged with an inert gas. Then, the substrate was exposed to 1 pulse of an SF₆/Ar plasma, wherein the pulse was for a duration of 15 seconds. The SF₆/Ar plasma was formed by flowing the SF₆ and Ar materials through ICP reactor 207 at a temperature of 200° C. while applying an electric power of 200 W to the materials. A flow rate ratio of the Ar to the SF₆ was 15:30. After the pulsing of the SF₆/Ar plasma, the substrate was again purged with an inert gas, thus completing one cycle of the ALD coating process. This cycle was repeated 600 times until the coating process produced the 31.8 nm average thick coating. The thickness of the produced ALD coating was measured on a left portion of the substrate, a right portion of the substrate, a top portion of the substrate, a bottom portion of the substrate, and a central portion to determine the thickness uniformity of the coating. Additionally, the refractive index of the coated substrate at a wavelength of 550 nm was measured at these same locations. The results are shown below in Table 1.

TABLE 1

| | Portions of Coated Substrate | | | | | | |
|---|---|---|---|---|---|---|---|
| | Right | Left | Top | Bottom | Central | | Variation |
| | Portion | Portion | Portion | Portion | Portion | Average | (%) |
| Thickness (nm) | 33.3 | 30.8 | 31.2 | 32.4 | 31.5 | 31.8 | 2.58 |
| Refractive Index | 1.559 | 1.556 | 1.559 | 1.558 | 1.559 | 1.558 | 0.068 |

As shown in Table 1 above, the ALD coating 30 in this exemplary example has a very uniform thickness, thus advantageously providing a uniform refractive index across the coated substrate. Refractive index, as disclosed herein, is measured by fitting data from a variable angle spectroscopic ellipsometer (Woollam VUV-Vase Ellipsometer, scan from 150 nm to 1600 nm wavelength, incident angle from 45 to about 80 degrees) using CompleteEASE™ software with a Cauchy model.

FIG. 6 shows a plot of refractive index vs. wavelength for a first optical component 300 comprising a glass substrate coated with a 24 nm thick LaF₃ ALD coating using the processes disclosed herein and for a second optical component 310 comprising the same glass substrate but coated with a 35 nm thick LaF₃ PVD coating. As shown in FIG. 6, both first optical component 300 and second optical component 310 comprise similar refractive index values over the wavelengths shown, showing that the ALD coating processes disclosed herein provide similar coating uniformity as that of the PVD process. In particular, both first and second optical components 300, 310 comprise a refractive index of 1.72 at 193 nm. Furthermore, first optical component 300 comprises a refractive index of 1.61 at 550 nm and second optical component 310 comprises a very similar refractive index of 1.60 at 550 nm.

In embodiments, ALD coating 30 produced using the embodiments disclosed herein may be substantially free of carbon. In embodiments, ALD coating 30 may have a concentration of carbon of about 10,000 ppm or less, or about 5,000 ppm or less, or about 1,000 ppm or less, or less about 500 ppm or less, or about 100 ppm or less, or any range encompassing these endpoints. ALD coating 30 may have a carbon content of about 1.2 atomic % or less, or about 1 atomic % or less at a depth of 0.02 microns measured using secondary ion mass spectrometry. In some embodiments, the carbon content is in a range from about 0.01 atomic % to about 1.2 atomic %, or in a range from about 0.01 atomic % to about 1 atomic % at a depth of 0.02 microns measured using secondary ion mass spectrometry. In particular, the carbon content is measured using an Cs micro-beam ion gun with the following parameters: (i) energy (volts) 1000, (ii) scan size-X: 400.0 micrometers (μm), (iii) scan size-Y: 400.0 micrometers (μm), (iv) beam current: 20 nanoamperes (nA), (v) primary beam angle: 45 degrees, and (vi) sputter rate: 2.9×10⁻⁵ micrometers/second. Data was normalized based on a standard sample with controlled concentration of carbon.

In embodiments, ALD coating 30 produced using the embodiments disclosed herein may also be substantially free of sulfur. In embodiments, ALD coating 30 may have a concentration of sulfur of about 1,000 ppm or less, or about 750 ppm or less, or about 500 ppm or less, or about 250 ppm or less, or about 200 ppm or less, or about 150 ppm or less, or about 100 ppm or less, or about 75 ppm or less, or about 50 ppm or less, or about 40 ppm or less, or about 30 ppm or less, or less about 20 ppm or less, or about 10 ppm or less, or about 5 ppm or less, or about 1 ppm or less, or any range encompassing these endpoints. Additionally or alternatively, ALD coating 30 may have sulfur content of greater than 0 ppm, such as from greater than 0 ppm to about 1,000 ppm or less, or greater than 0 ppm to about 750 ppm or less, or greater than 0 ppm to about 500 ppm or less, or greater than 0 ppm to about 250 ppm or less, or greater than 0 ppm to about 200 ppm or less, or greater than 0 ppm to about 150 ppm or less, or greater than 0 ppm to about 100 ppm or less, or greater than 0 ppm to about 75 ppm or less, or greater than 0 ppm to about 50 ppm or less, or greater than 0 ppm to about 40 ppm or less, or greater than 0 ppm to about 30 ppm or less, or greater than 0 ppm to about 20 ppm or less, or greater than 0 ppm to about 10 ppm or less, or greater than 0 ppm to about 5 ppm or less, or greater than 0 ppm to about 1 ppm or less. The sulfur content is measured using an Cs micro-beam ion gun with the following parameters: (i) energy (volts) 1000, (ii) scan size-X: 400.0 micrometers (μm), (iii) scan size-Y: 400.0 micrometers (μm), (iv) beam current: 20 nanoamperes (nA), (v) primary beam angle: 45 degrees, and (vi) sputter rate: 2.9×10−5 micrometers/second. Data was normalized based on a standard sample with controlled concentration of sulfur.

In embodiments, ALD coating 30 produced using the embodiments disclosed herein may be substantially free of oxygen. In embodiments, ALD coating 30 may have a concentration of oxygen of about 10,000 ppm or less, or about 5,000 ppm or less, or about 1,000 ppm or less, or less about 500 ppm or less, or about 100 ppm or less, or any range encompassing these endpoints. ALD coating 30 may have an oxygen content of about 1.2 atomic % or less, or about 1 atomic % or less at a depth of 0.02 microns measured using secondary ion mass spectrometry. In some embodiments, the oxygen content is in a range from about 0.01 atomic % to about 1.2 atomic %, or in a range from about 0.01 atomic % to about 1 atomic % at a depth of 0.02 microns measured using secondary ion mass spectrometry. In particular, the oxygen content is measured using an Cs micro-beam ion gun with the following parameters: (i) energy (volts) 1000, (ii) scan size-X: 400.0 micrometers (μm), (iii) scan size-Y: 400.0 micrometers (μm), (iv) beam current: 20 nanoamperes (nA), (v) primary beam angle: 45 degrees, and (vi) sputter rate: 2.9×10−5 micrometers/second. Data was normalized based on a standard sample with controlled concentration of oxygen.

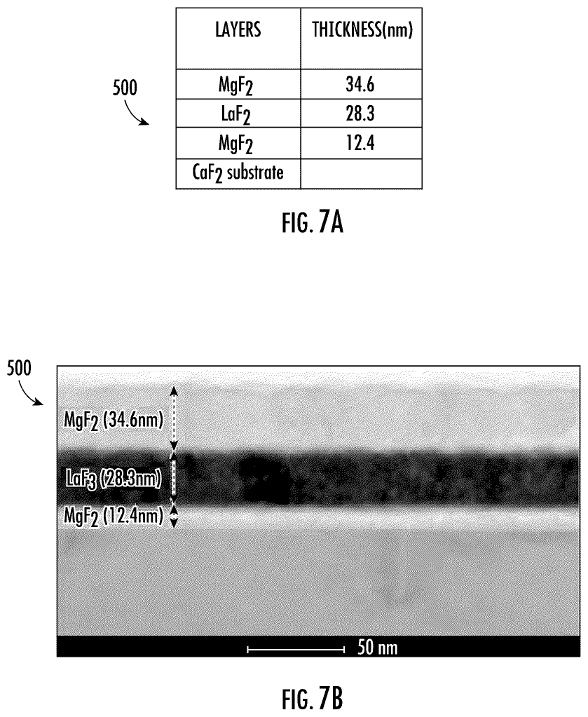

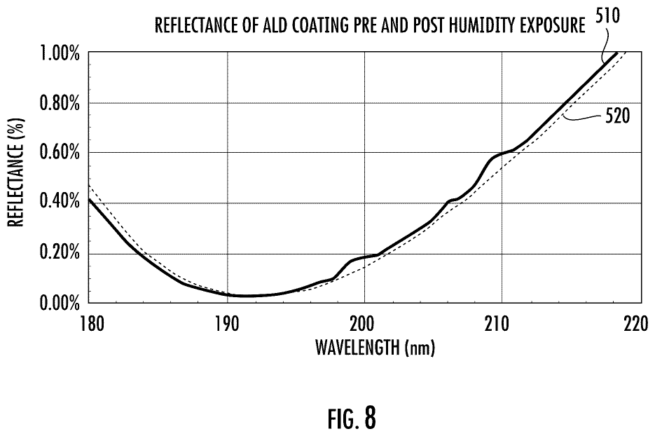

FIGS. 7A and 7A show another exemplary embodiment of an ALD coating 500 produced using the processes disclosed herein. As shown in FIGS. 7A and 7B, ALD coating 500 in this embodiment comprises two first layers 32 comprised of MgF₂ and one second layer 34 comprised of LaF₃. Furthermore, ALD coating 500 is deposited on a CaF₂ substrate. The thickness values of each layer of ALD coating 500 are shown in FIGS. 7A and 7B. ALD coating 500 was subjected to a humidity test to determine the stability of the coating as an AR coating. The humidity test included subjecting the coated substrate to an 80% humid atmosphere at a temperature of 80° C. for a duration of 6 hours. The reflectance of ALD coating 500 was measured before and after the humidity, the results of which are shown in FIG. 8. Specifically, reference numeral 510 shows the reflectance of ALD coating 500 before the humidity test and reference numeral 520 shows the reflectance of ALD coating 500 after the humidity test at an incident (θ) angle of 15 degrees. As shown in FIG. 8, the reflectance of ALD coating 500 is very similar from before the humidity test to after, thus showing the durability and stability of the coating.

In embodiments, the ALD coatings produced using the embodiments disclosed herein are AR coatings. In some embodiments, ALD coating 30 comprises an optical absorption value of about 1% or less, or about 0.75% or less, or about 0.5% or less for light having a wavelength in the DUV range of 157 nm and from 193 nm to 266 nm and at all incident angles (0) within the range of 15 degrees or less. Thus, the optical absorption value disclosed herein is for each and every wavelength within the DUV range of 157 nm and from 193 nm to 266 nm. An “optical absorption value” is the percentage of light that is absorbed by a layer or film of material for a given wavelength of light and a given incident angle (θ) of the light. Absorption of light means that photons of the light neither reflect from nor pass through the layer or film but instead are taken up by the layer or film and released as energy, usually in the form of heat. A given wavelength of light may be a specific wavelength value or a range of wavelength values. For a range of wavelength values, an optical absorption is calculated by averaging the optical absorption of each whole number wavelength in the range of wavelengths. An incident angle (θ) is the angle at which the light impinges upon a surface of the layer or film of material measured relative to a line perpendicular to the surface at the location of incidence.

The optical absorption values described herein are measured according to the following procedures. The film of material tested was deposited on an 8655 fused silica substrate. The film of material was deposited on opposing sides of the fused silica substrate and the total optical absorption through the film on both sides of the substrate was determined. An Agilent Cary5000 UV-Vis-NIR Spectrophotometer having a wavelength range of 400 nm to 200 nm was used to measure optical transmittance and optical reflection values. The following instrument parameters were used: (i) angle of incidence: within the range of 15 degrees or less, (ii) data interval: 1 nm, 150 nm/min, and (iii) average measurement time: 0.4 seconds. No polarizer was used. Transmittance and reflectance measurements were corrected to the corresponding ratio of the true surface reflectance and transmittance of 8655 fused silica to the measured surface reflectance and transmittance. The standard Fresnel equations for reflected intensity of s- and p-polarizations were used for this correlation. Optical absorption was calculated using the formula:

$$\% A = 100 - \% T - \% R$$

where: % A equals optical absorption, % T equals percent of light transmitted, and % R equals percent of light reflected.

In embodiments, ALD coating 30 produced using the embodiments disclosed herein comprises an optical transmittance value of about 94% or more, or about 95% or more, or about 96% or more, or about 97% or more, or about 98% or more, or about 99% or more for light having a wavelength in the DUV range of 157 nm and from 193 nm to 266 nm and at all incident angles (θ) within the range of 15 degrees or less. Thus, the optical transmittance disclosed herein is for each and every wavelength within the DUV range of 157 nm and from 193 nm to 266 nm. An “optical transmittance value” is the percentage of light that passes through a layer or film of material for a given wavelength of light and a given incident angle (θ) of the light. A given wavelength of light may be a specific wavelength value or a range of wavelength values. For a range of wavelength values, an optical transmittance is calculated by averaging the optical transmittance of each whole number wavelength in the range of wavelengths. The optical transmittance values disclosed herein are measured using the Agilent Cary5000 UV-Vis-NIR Spectrophotometer according to the measurement steps discussed above.

In embodiments, ALD coating 30 produced using the embodiments disclosed herein comprises an optical reflectance value of about 5% or less, or about 4% or less, or about 3% or less, or about 2% or less, or about 1% or less for light having a wavelength in the DUV range of 157 nm and from 193 nm to 266 nm and at all incident angles (θ) within the range of 15 degrees or less. Thus, the optical reflectance disclosed herein is for each and every wavelength within the DUV range of 157 nm and from 193 nm to 266 nm. An “optical reflectance value” is the percentage of light that reflects off the surface of a layer or film of material for a given wavelength of light and a given incident angle (θ) of the light. A given wavelength of light may be a specific wavelength value or a range of wavelength values. For a range of wavelength values, optical reflectance is calculated by averaging the optical reflectance of each whole number wavelength in the range of wavelengths. The optical reflectance values disclosed herein are measured using the Agilent Cary5000 UV-Vis-NIR Spectrophotometer according to the measurement steps discussed above.

In embodiments, coated optical component 10 is a high NA objective lens coated with an LaF₃/MgF₂ or LaF₃/AlF₃ ALD coating. In embodiments, ALD coating is an AR coating.

According to a first aspect, a coated optical component comprising a substrate comprising at least one surface and an atomic layer deposition coating deposited on the surface of the substrate, the atomic layer deposition coating comprising a first layer of lanthanum fluoride. Furthermore, the atomic layer deposition coating comprising a carbon concentration of about 10,000 ppm or less, an oxygen concentration of about 10,000 ppm or less, and a sulfur concentration of about 500 ppm or less.

According to a second aspect, the coated optical component of the first aspect, wherein the atomic layer deposition coating comprises at least a second layer of magnesium fluoride or aluminum fluoride.

According to a third aspect, the coated optical component of the first or second aspects, wherein the atomic layer deposition coating comprises two first layers of lanthanum fluoride and one second layer of magnesium fluoride.

According to a fourth aspect, the coated optical component of any one of the first through third aspects, wherein the surface of the substrate has a steepness value in a range from 0.5 to 1.0, the steepness value being equal to a radius of curvature of the surface divided by a clear aperture of the coated optical component.

According to a fifth aspect, the coated optical component of any one of the first through fourth aspects, wherein a thickness of the first layer of the atomic layer deposition coating is in a range from about 2 nm to about 50 nm.

According to a sixth aspect, the coated optical component of the fifth aspect, wherein the thickness of the first layer of the atomic layer deposition coating is in a range from about 10 nm to about 30 nm.

According to a seventh aspect, the coated optical component of the sixth aspect, wherein a total thickness of the atomic layer deposition coating is in a range from about 20 nm to about 200 nm.

According to an eighth aspect, the coated optical component of the seventh aspect, wherein the total thickness of the atomic layer deposition coating is in a range from about 40 nm to about 180 nm.

According to a ninth aspect, the coated optical component of any one of the first through eighth aspects, wherein the atomic layer deposition coating comprises at least a plurality of layers, the plurality of layers comprising the first layer and a second layer, the first layer comprising a different metal fluoride from the second layer.

According to a tenth aspect, the coated optical component of the ninth aspect, wherein the second layer comprises a higher refractive index than the first layer.

According to an eleventh aspect, the coated optical component of the tenth aspect, wherein the refractive index of the second layer is in a range from about 1.65 to about 1.75.

According to a twelfth aspect, the coated optical component of the tenth aspect, wherein the refractive index of the first layer is in a range from about 1.30 to about 1.60.

According to a thirteenth aspect, the coated optical component of any one of the first through twelfth aspects, wherein the atomic layer deposition coating has a surface (Ra) of about 1.5 nm or less.

According to a fourteenth aspect, the coated optical component of the thirteenth aspect, wherein the surface roughness (Ra) is about 1.00 nm or less.

According to a fifteenth aspect, the coated optical component of the fourteenth aspect, wherein the surface roughness (Ra) is about 0.75 nm or less.

According to a sixteenth aspect, the coated optical component of any one of the first through fifteenth aspects, wherein a thickness of the atomic layer deposition coating varies by about 5% or less across an entirety of the surface from an average thickness of the atomic layer deposition coating.

According to a seventeenth aspect, the coated optical component of any one of the first through sixteenth aspects, wherein the carbon concentration of the atomic layer deposition coating is about 5,000 ppm or less.

According to an eighteenth aspect, the coated optical component of any one of the first through seventeenth aspects, wherein the oxygen concentration of the atomic layer deposition coating is about 5,000 ppm or less.

According to a nineteenth aspect, the coated optical component of any one of the first through eighteenth aspects, wherein the sulfur concentration of the atomic layer deposition coating is about 100 ppm or less.

According to a twentieth aspect, the coated optical component of any one of the first through nineteenth aspects, wherein the atomic layer deposition coating comprises an optical absorption value of about 1% or less for light having a wavelength in a range from 193 nm to 266 nm and at all incident angles (θ) within the range of 15 degrees or less.

According to a twenty-first aspect, the coated optical component of any one of the first through twentieth aspects, wherein the atomic layer deposition coating comprises an optical transmittance value of about 94% or more for light having a wavelength in a range from 193 nm to 266 nm and at all incident angles (θ) within the range of 15 degrees or less.

According to a twenty-second aspect, the coated optical component of any one of the first through twenty-first aspects, wherein the atomic layer deposition coating comprises an optical reflectance value of about 5% or less for light having a wavelength in a range from 193 nm to 266 nm and at all incident angles (θ) within the range of 15 degrees or less.

According to a twenty-first aspect, the coated optical component of the twenty-second aspect, wherein the atomic layer deposition coating comprises an optical reflectance value of about 0.5% or less for light having a wavelength of 193 nm and at all incident angles (θ) within the range of 15 degrees or less.

According to a twenty-fourth aspect, the coated optical component of any one of the first through twenty-third aspects, wherein the substrate is a lens, window, objective, prism, beam splitter, filter, and/or mirror.

According to a twenty-fifth aspect, the coated optical component of any one of the first through twenty-fourth aspects, wherein the substrate comprises calcium fluoride, magnesium fluoride, silicon, or silicate glass.

According to a twenty-sixth aspect, the coated optical component of the twenty-fifth aspect, wherein the substrate comprises calcium fluoride.

According to a twenty-seventh aspect, a process of coating an optical component with an atomic layer deposition coating, the process comprising converting a fluorine source into a sulfur hexafluoride-based plasma by generating a plasma of the fluorine source at a temperature from about 5° C. to about 20° C. while applying an electric current having a power from about 100 Watts to about 400 Watts and exposing a surface of a substrate to one cycle of an atomic layer deposition coating process in an atomic layer deposition chamber by: (i) exposing the surface of the substrate to one or more pulses of a lanthanum-based metal precursor while heating the substrate to a temperature from about 100° C. to about 400° C. and (ii) exposing the surface of the substrate to one or more pulses of the sulfur hexafluoride-based plasma while heating the substrate to a temperature from about 100° C. to about 400° C.

According to a twenty-eighth aspect, the process of the twenty-seventh aspect, wherein the sulfur hexafluoride-based plasma is derived from sulfur hexafluoride and argon.

According to a twenty-ninth aspect, the process of the twenty-seventh or twenty-eighth aspects, wherein each pulse of the lanthanum-based metal precursor is from about 0.01 seconds to about 10 seconds in duration.

According to a thirtieth aspect, the process of the twenty-ninth aspect, wherein the cycle comprises two or more pulses of the lanthanum-based metal precursor.

According to a thirty-first aspect, the process of any one of the twenty-seventh through thirtieth aspects, wherein each pulse of the sulfur hexafluoride-based plasma is from about 0.01 seconds to about 30 seconds in duration.

According to a thirty-second aspect, the process of the thirty-first aspect, wherein the cycle comprises one pulse of the sulfur hexafluoride-based plasma.

According to a thirty-third aspect, the process of any one of the twenty-seventh through thirty-second aspects, wherein each pulse of the sulfur hexafluoride-based plasma is longer in duration than each pulse of the lanthanum-based metal precursor.

According to a thirty-fourth aspect, the process of any one of the twenty-seventh through thirty-third aspects, wherein the cycle deposits a first deposition layer of the atomic layer deposition coating on the surface of the substrate, and the process further comprises repeating the cycle to deposit a second deposition layer of the atomic layer deposition coating on the surface of the substrate.

According to a thirty-fifth aspect, the process of any one of the twenty-seventh through thirty-fourth aspects, further comprising heating the atomic layer deposition chamber to a temperature from about 10° C. to about 15° C. while exposing the surface of the substrate to the pulses of the lanthanum-based metal precursor and the sulfur hexafluoride-based plasma.

According to a thirty-sixth aspect, the process of any one of the twenty-seventh through thirty-fifth aspects, further comprising converting the fluorine source into the sulfur hexafluoride-based plasma by heating the fluorine source to a temperature from about 10° C. to about 15° C. and applying the electric current having a power from about 125 Watts to about 375 Watts.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A coated optical component comprising:
a substrate comprising at least one surface; and
an atomic layer deposition coating deposited on the at least one surface of the substrate, the atomic layer deposition coating comprising a first layer of lanthanum fluoride,
the atomic layer deposition coating comprising a carbon concentration of about 10,000 ppm or less, an oxygen concentration of about 10,000 ppm or less, and a sulfur concentration of about 500 ppm or less.

2. The coated optical component of claim 1, wherein the atomic layer deposition coating comprises at least a second layer, the second layer comprising magnesium fluoride or aluminum fluoride.

3. The coated optical component of claim 1, wherein the atomic layer deposition coating comprises two first layers of lanthanum fluoride and one second layer of magnesium fluoride.

4. The coated optical component of claim 1, wherein the surface of the substrate has a steepness value in a range from 0.5 to 1.0, the steepness value being equal to a radius of curvature of the surface divided by a clear aperture of the coated optical component.

5. The coated optical component of claim 1, wherein a thickness of the first layer of the atomic layer deposition coating is in a range from about 2 nm to about 50 nm.

6. The coated optical component of claim 1, wherein a total thickness of the atomic layer deposition coating is in a range from about 20 nm to about 200 nm.

7. The coated optical component of claim 6, wherein the total thickness of the atomic layer deposition coating is in a range from about 40 nm to about 180 nm.

8. The coated optical component of claim 1, wherein the atomic layer deposition coating comprises at least a plurality of layers, the plurality of layers comprising the first layer and a second layer, the first layer comprising a different metal fluoride from the second layer.

9. The coated optical component of claim 8, wherein the second layer comprises a higher refractive index than the first layer at a wavelength of 193 nm.

10. The coated optical component of claim 9, wherein the refractive index of the second layer is in a range from about 1.65 to about 1.75 at a wavelength of 193 nm.

11. The coated optical component of claim 9, wherein the refractive index of the first layer is in a range from about 1.30 to about 1.60 at a wavelength of 193 nm.

12. The coated optical component of claim 1, wherein the atomic layer deposition coating has a surface (Ra) of about 1.5 nm or less.

13. The coated optical component of claim 1, wherein a thickness of the atomic layer deposition coating varies by about 5% or less across an entirety of the surface from an average thickness of the atomic layer deposition coating.

14. The coated optical component of claim 1, wherein the carbon concentration of the atomic layer deposition coating is about 5,000 ppm or less.

15. The coated optical component of claim 1, wherein the oxygen concentration of the atomic layer deposition coating is about 5,000 ppm or less.

16. The coated optical component of claim 1, wherein the sulfur concentration of the atomic layer deposition coating is about 100 ppm or less.

17. The coated optical component of claim 1, wherein the atomic layer deposition coating comprises an optical absorption value of about 1% or less for light having a wavelength at each and every wavelength within a range from 193 nm to 266 nm and at all incident angles (θ) within the range of 15 degrees or less.

18. The coated optical component of claim 1, wherein the atomic layer deposition coating comprises an optical reflectance value of about 0.5% or less for light having a wavelength of 193 nm and at all incident angles (θ) within the range of 15 degrees or less.

19. The coated optical component of claim 1, wherein the substrate is a lens, window, objective, prism, beam splitter, filter, and/or mirror.

20. The coated optical component of claim 1, wherein the substrate comprises calcium fluoride.
